(19) United States
(12) Patent Application Publication
(10) Pub. No.: US 2014/0261650 A1
(43) Pub. Date: Sep. 18, 2014

(54) SOLAR CELL

(71) Applicant: Samsung Electronics Co., Ltd., Suwon-Si (KR)

(72) Inventors: Yun Gi KIM, Yongin-si (KR); Takkyun RO, Hwaseong-si (KR)

(73) Assignee: Samsung Electronics Co., Ltd., Suwon-Si (KR)

(21) Appl. No.: 14/196,129

(22) Filed: Mar. 4, 2014

(30) Foreign Application Priority Data
Mar. 13, 2013 (KR) 10-2013-0026844

(51) Int. Cl. H01L 31/0352

(52) U.S. Cl. CPC H01L 31/035218
USPC 136/255

(57) ABSTRACT

A solar cell includes a first electrode, a second electrode spaced apart from the first electrode, and a light absorption layer between the first electrode and the second electrode. The light absorption layer includes a first absorption sublayer, a second absorption sublayer and a third absorption sublayer. The first absorption sublayer contacts the first electrode and includes a first quantum dot, the second absorption sublayer is between the first absorption sublayer and the third absorption sublayer and includes a second quantum dot, and the third absorption sublayer contacts the second electrode and includes a third quantum dot. The second quantum dot is larger than the first quantum dot and the third quantum dot.

### CROSS REFERENCE TO RELATED APPLICATION

This application claims priority under 35 U.S.C. §119 to Korean Patent Application No. 10-2013-0026844 filed in the Korean Intellectual Property Office on Mar. 13, 2013, the entire contents of which are incorporated herein by reference.

### BACKGROUND

(a) Field

Some example embodiments relate to a solar cell.

(b) Description of the Related Art

Fossil fuels, such as coal and petroleum, are used as energy sources. However, fossil fuels are being exhausted and cause global warming and environmental pollution. Solar light, tidal power, wind power, geothermal heat and the like are being studied as alternative energy sources for replacing fossil fuels.

Among them, various materials and devices are being developed for solar cells that convert solar light into electricity. In particular, solar cells using quantum dots are suggested. However, conventional solar cells including quantum dots may not show a desired performance.

### SUMMARY

According to an example embodiment, a solar cell includes a first electrode, a second electrode spaced apart from the first electrode, and a light absorption layer between the first electrode and the second electrode. The light absorption layer includes a first absorption sublayer, a second absorption sublayer and a third absorption sublayer. The first absorption sublayer contacts the first electrode and includes a first quantum dot, the second absorption sublayer is between the first absorption sublayer and the third absorption sublayer and includes a second quantum dot, and the third absorption sublayer contacts the second electrode and includes a third quantum dot. The second quantum dot is larger than the first quantum dot and the third quantum dot.

The first quantum dot and the third quantum dot may be the same size.

The first absorption sublayer may include at least one layer of the first quantum dot, the second absorption sublayer may include at least two layers of the second quantum dot, and the third absorption sublayer may include at least one layer of the third quantum dot.

The first absorption sublayer may have a bandgap from about 1.8 eV to about 5 eV, the second absorption sublayer may have a bandgap from about 0.8 eV to about 1.8 eV, and the third absorption sublayer may have a bandgap from about 1.8 eV to about 5 eV.

The first absorption sublayer may be configured to absorb light having a wavelength from about 350 nm to about 650 nm, the second absorption sublayer may be configured to absorb light having a wavelength from about 650 nm to about 1,200 nm, and the third absorption sublayer may be configured to absorb light having a wavelength from about 350 nm to about 650 nm.

The first absorption sublayer may have a bandgap from about 0.8 eV to about 1.8 eV, the second absorption sublayer may have a bandgap from about 0.4 eV to about 0.9 eV, and the third absorption sublayer may have a bandgap from about 0.8 eV to about 1.8 eV.

The first absorption sublayer may be configured to absorb light having a wavelength from about 650 nm to about 1,200 nm, the second absorption sublayer sublayer may be configured to absorb light having a wavelength from about 1,100 nm to about 2,500 nm, and the third absorption sublayer may be configured to absorb light having a wavelength from about 650 nm to about 1,200 nm.

The first absorption sublayer may have a bandgap from about 1.8 eV to about 5 eV, the second absorption sublayer may have a bandgap from about 0.4 eV to about 0.9 eV, and the third absorption sublayer may have a bandgap from about 1.8 eV to about 5 eV.

The first absorption sublayer may be configured to absorb light having a wavelength from about 350 nm to about 650 nm, the second absorption sublayer may be configured to absorb light having a wavelength from about 1,100 nm to about 2,500 nm, and the third absorption sublayer may be configured to absorb light having a wavelength from about 350 nm to about 650 nm.

The solar cell may further include a fourth absorption sublayer between the first absorption sublayer and the second absorption sublayer, the fourth absorption sublayer including a fourth quantum dot larger than the first, second and third quantum dots, and a fifth absorption sublayer between the second absorption sublayer and the third absorption sublayer, the fifth absorption sublayer including a fifth quantum dot larger than the first to third quantum dots.

The fourth quantum dot and the fifth quantum dot may be the same size.

The solar cell may further include a sixth absorption sublayer between the second absorption sublayer and the fourth absorption sublayer, the sixth absorption sublayer including a sixth quantum dot larger than the second, fourth, and fifth quantum dots, and a seventh absorption sublayer between the second absorption sublayer and the fifth absorption sublayer, the seventh absorption sublayer including a seventh quantum dot larger than the second, fourth, and fifth quantum dots.

The fourth quantum dot and the fifth quantum dot may be the same size, the sixth quantum dot, the first quantum dot and the third quantum dot may have the same size, and the seventh quantum dot, the first quantum dot and the third quantum dot may have the same size.

Each of the first absorption sublayer and the third absorption sublayer may have a bandgap from about 1.8 eV to about 5 eV, the second absorption sublayer may have a bandgap from about 0.8 eV to about 1.8 eV, and each of the fourth absorption sublayer and the fifth absorption sublayer may have a bandgap from about 0.4 eV to about 0.9 eV.

Each of the first absorption sublayer and the third absorption sublayer may be configured to absorb light having a wavelength from about 350 nm to 650 nm, the second absorption sublayer may be configured to absorb light having a wavelength from about 650 nm to about 1,200 nm, and each of the fourth absorption sublayer and the fifth absorption sublayer may be configured to absorb light having a wavelength from about 1,100 nm to about 2,500 nm.

The first, second, third, fourth and fifth absorption sublayers may have a same thickness.

The first, second, third, fourth and fifth absorption sublayers may have a symmetrical structure with respect to the third absorption sublayer.

### BRIEF DESCRIPTION OF THE DRAWINGS

FIG. 1 is a schematic sectional view of a solar cell according to an example embodiment.

FIG. 2 is a schematic sectional view of a solar cell according to an example embodiment.

FIG. 3 is a schematic sectional view of a solar cell according to an example embodiment.

### DETAILED DESCRIPTION

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference numerals in the drawings denote like elements, and thus their description may be omitted. In the drawing, parts having no relationship with the explanation are omitted for clarity.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

A solar cell according to example embodiments is described in detail with reference to FIG. 1.

FIG. 1 is a schematic sectional view of a solar cell according to an example embodiment.

Referring to FIG. 1, a solar cell 100 according to an example embodiment includes a first electrode (or a lower electrode) 120, a light absorption layer 140, and a second electrode (or an upper electrode) 160, which are deposited in sequence.

The first electrode 120 may include a transparent conductive material, for example, indium tin oxide (ITO) and indium zinc oxide (IZO). The first electrode 120 may be disposed on a substrate (not shown).

The second electrode 160 is disposed on the light absorption layer 140, and may include a low-resistivity conductor, for example, copper (Cu), aluminum (Al), silver (Ag), gold (Au), carbon nanotube (CNT), graphene, and/or ITO.

The light absorption layer 140 is disposed between the first electrode 120 and the second electrode 160, and may absorb photons to produce electrons and holes. The light absorption layer 140 may include a first absorption sublayer 142, a second absorption sublayer 144, and a third absorption sublayer 146.

The first absorption sublayer 142 may contact the first electrode 120, and the third absorption sublayer 146 may contact the second electrode 160. The second absorption sublayer 144 may be disposed between the first absorption sublayer 142 and the third absorption sublayer 146. The first absorption sublayer 142 may include a plurality of first quantum dots (or nanoparticles) 152 that may have substantially the same size. The second absorption sublayer 144 may include a plurality of second quantum dots 154 that may have substantially the same size. The third absorption sublayer 146 may include a plurality of third quantum dots 156 that may have substantially the same size. The first quantum dots 152 may be in contact with the first electrode 120, and the third quantum dots 156 may be in contact with the second electrode 160. The first quantum dots 152 and the third quantum dots 156 may be substantially the same size. The second quantum dots 154 may be larger than the first quantum dots 152 and the third quantum dots 156.

At least one of the first, second, and third absorption sublayers 142, 144 and 146 may further include ligands (not shown) that may provide distance between the quantum dots 152, 154 and 156 within the first, second and third absorption sublayers 142, 144 and 146, respectively. The ligands (not shown) may fix the first quantum dots 152 to the first electrode 120, the second quantum dots 154 to the first absorption sublayer 142 and/or the third absorption sublayer 146, and the third quantum dots 156 to the second electrode 160. For example, the first absorption sublayer 142 may further include ligands, and the ligands instead of the first quantum dots 152 may contact the first electrode 120. Similarly, the third absorption sublayer 146 may further include ligands, and the ligands instead of the third quantum dots 156 may contact the second electrode 160.

An energy bandgap of the second absorption sublayer 144 may be smaller than bandgaps of the first and third absorption sublayers 142 and 146. According to an example embodiment, the bandgap of each of the first and third absorption sublayers 142 and 146 may be, for example, from about 1.8 eV to about 5 eV, in particular about 2.3 eV, and the bandgap of the second absorption sublayer 144 may be, for example, from about 0.8 eV to about 1.8 eV, in particular about 1.4 eV. According to an alternative example embodiment, the bandgap of each of the first and third absorption sublayers 142 and 146 may be, for example, from about 0.8 eV to about 1.8 eV, in particular about 1.4 eV, and the bandgap of the second absorption sublayer 144 may be, for example, from about 0.4 eV to about 0.9 eV, in particular about 0.8 eV. According to an alternative example embodiment, the bandgap of each of the first and third absorption sublayers 142 and 146 may be, for example, from about 1.8 eV to about 5 eV, in particular about 2.3 eV, the bandgap of the second absorption sublayer 144 may be, for example, from about 0.4 eV to about 0.9 eV, in particular about 0.8 eV.

The absorption sublayers 142, 144 and 146 having different bandgaps may absorb light with various wavelengths. For example, the absorption sublayer 142, 144 or 146 having a bandgap from about 1.8 eV to about 5 eV may absorb light having a wavelength from about 350 nm to about 650 nm, the absorption sublayer 142, 144 or 146 having a bandgap from about 0.8 eV to about 1.8 eV may absorb light having a wavelength from about 650 nm to about 1,200 nm, and the absorption sublayer 142, 144 or 146 having a bandgap from about 0.4 eV to about 0.9 eV may absorb light having a wavelength from about 1,100 nm to about 2,500 nm.

The difference in the bandgap between the absorption sublayers 142, 144 and 146 may be obtained by differentiating sizes of the quantum dots 152, 154 or 156 contained in the absorption sublayers 142, 144 and 146. For example, the second quantum dot 154 may be larger than the first quantum dot 152 and the third quantum dot 156 so that the bandgap of the second absorption sublayer 144 may be lower than each of the bandgaps of the first and third absorption sublayers 142 and 146.

According to an example embodiment, the first quantum dot 152 may have substantially the same size as the third quantum dot 156.

According to an example embodiment, the second absorption sublayer 144 may include at least two layers of the second quantum dots 154, and each of the first and third absorption sublayers 142 and 146 may include at least one layer of the first or third quantum dots 152 or 156. For example, FIG. 1 shows that each of the first and third absorption sublayers 142 and 146 has a single layer of the quantum dots 152 or 156 while the second absorption sublayer 144 has two layers of the quantum dots 154.

Magnitudes of the bandgaps of the absorption sublayers 142, 144 and 146 may depend on the sizes of the quantum dots 152, 154 and 156, and a minimum thickness of each of the absorption sublayers 142, 144 and 146 may be obtained based on the size of the quantum dot 152, 154 or 156 and absorption coefficient.

When the bandgaps of the first and third absorption sublayers 142 and 146 are about 2.3 eV, the bandgap of the second absorption sublayer 144 is about 1.4 eV, and the quantum dots 152, 154 and 156 is made of MnSi, a diameter of each of the first and third quantum dots 152 and 156 may be about 3.68 nm, and a diameter of the second quantum dot 154 may be about 5.82 nm. Since the absorption coefficient for the bandgap of about 2.3 eV may be about 2536517.1, the minimum thickness of each of the first and third absorption sublayers 142 and 146 may be about 3.94 nm. Since the absorption coefficient for the bandgap of about 1.4 eV may be about 1137167.9, the minimum thickness of the second absorption sublayer 144 may be about 5.82 nm. Therefore, nearly a single layer of the first quantum dots 152 may form the first absorption sublayer 142 having the minimum thickness, and similarly, nearly a single layer of the third quantum dots 156 may form the third absorption sublayer 146 having the minimum thickness. In addition, nearly two layers of the second quantum dots 154 may form the second absorption sublayer 144 having the minimum thickness.

FIG. 1 shows that the quantum dots 152, 154 and 156 are spherical, but the shape of the quantum dots 152, 154 and 156 are not limited thereto. For the spherical quantum dots 152, 154 and 156 spherical quantum dots, the above-described term “diameter” may denote the length or the size of the quantum dots 152, 154 and 156.

Use of the quantum dots 152, 154 or 156 may make the light absorption layer 140 thin.

Since the second absorption sublayer 144 including the large quantum dots 154 is disposed between the first absorption sublayer 142 and the third absorption sublayer 146 including the small quantum dots 152 and 156, an open circuit voltage (Voc) may be substantially the same as a voltage of the outer sublayer 142 or 146, and a short-circuit current (Jsc) may be a sum of the currents of the first to third absorption sublayers 142, 144 and 146. The theoretical efficiency of the solar cell 100 may reach about 45%.

In addition, since the light absorption layer 140 including the quantum dots 152, 154 and 156 includes no junction structure, there is no interlayer recombination of electrons and holes occurring at the junction, and the short-circuit current can be obtained only by mutual transit between the quantum dots 152, 154 and 156.

The quantum dots 152, 154 and 156 may include a material having high absorption coefficient, for example, MnSi, CoSb₃, SnTe, LaSb, and CeN. The ligands may include a conductive insulator, for example, a conductive oxide or a conductive nitride, which include MgO, TiOₓ, and TiON. Alternatively, the ligands may include ethanedithiol (EDT), benzenedithiol (BDT), and mercaptopropionic acid (MPA), for example. However, the materials for the quantum dots 152, 154 and 156 and ligands are not limited thereto.

A solar cell according to an example embodiment is described in detail with reference to FIG. 2.

FIG. 2 is a schematic sectional view of a solar cell according to an example embodiment.

Referring to FIG. 2, a solar cell 200 according to an example embodiment includes a first electrode (or a lower electrode) 220, a light absorption layer 240, and a second electrode (or an upper electrode) 260, which are deposited in sequence.

The light absorption layer 240 is disposed between the first electrode 220 and the second electrode 260, and may absorb photons to produce electrons and holes. The light absorption layer 140 may include a first absorption sublayer 241, a second absorption sublayer 242, a third absorption sublayer 243, a fourth absorption sublayer 244, a fifth absorption sublayer 245, a sixth absorption sublayer 246, and a seventh absorption sublayer 247.

Among the first to seventh absorption sublayers 241-247, the outermost sublayers, i.e., the first absorption sublayer 241 and the seventh absorption sublayer 247 may contact the first electrode 220 and the second electrode 260, respectively. The fifth absorption sublayer 245 is disposed on the innermost sublayer, i.e., the fourth absorption sublayer 244, and the third absorption sublayer 243 is disposed the fourth absorption sublayer 244. The second absorption sublayer 242 is disposed between the first absorption sublayer 241 and the third absorption sublayer 243, and the sixth absorption sublayer 246 is disposed between the fifth absorption sublayer 245 and the seventh absorption sublayer 247.

The first to seventh absorption sublayers 241-247 may include first to seventh quantum dots (or nanoparticles) 251-257, respectively. The first quantum dots 251 may contact the first electrode 220, and the seventh quantum dots 257 may contact the second electrode 260. The quantum dots 251-257 in each of the absorption sublayers 241-247 may have substantially the same size. At least one of the first to seventh absorption sublayers 241-247 may further include ligands (not shown) that may keep distances between the quantum dots 251-257 and may fix the quantum dots 251-257. For example, the first absorption sublayer 241 may further include ligands, and the ligands instead of the first quantum dots 251 may contact the first electrode 220. Similarly, the seventh absorption sublayer 247 may further include ligands, and the ligands instead of the seventh quantum dots 257 may contact the second electrode 260.

The outermost quantum dots, i.e., the first and seventh quantum dots 251 and 257 may be the smallest, and the inner quantum dots, i.e., the second to sixth quantum dots 252-256 may be equal to or larger than the first and seventh quantum dots 251 and 257 in size. Among the second to sixth quantum dots 252-256, the second quantum dot 252 adjacent to the first quantum dot 251, the sixth quantum dot 256 adjacent to the seventh quantum dot 257, and the innermost quantum dot, i.e., the fourth quantum dot 254 may be larger than the first and seventh quantum dots 251 and 257 in size. The fourth quantum dot 254 may be smaller than the second and sixth quantum dots 252 and 256 in size. The third quantum dot 253 disposed between the second quantum dot 252 and the fourth quantum dot 254 and the fifth quantum dot 255 disposed between the fourth quantum dot 254 and the sixth quantum dot 256 may be smaller in size than the second, fourth, and sixth quantum dots 252, 254 and 256.

According to an example embodiment, the sizes of the first quantum dot 251 to the seventh quantum dots 257 may be small-large-small-medium-small-large-small in sequence.

According to an example embodiment, the first quantum dot 251 may have substantially the same size as the seventh quantum dot 257.

According to an example embodiment, each of the third and fifth quantum dots 253 and 255 may have substantially the same size as each of the first and seventh quantum dots 251 and 257.

According to an example embodiment, the second quantum dot 252 may have substantially the same size as the sixth quantum dot 256.

According to an example embodiment, an arrangement of the first to seventh quantum dots 251-257 may be symmetrical in the vertical direction.

According to an example embodiment, the structures of the first to seventh absorption sublayers 241-247 may be symmetrical with respect to the fourth absorption sublayer 244.

According to an example embodiment, the bandgap of each of the first, third, fifth, and seventh absorption sublayers 241, 243, 245 and 247 may be about 1.8 eV to about 5 eV, for example, about 2.3 eV. The bandgap of the fourth absorption sublayer 244 may be about 0.8 eV to about 1.8 eV, for example, about 1.4 eV. The bandgap of each of the second and sixth absorption sublayers 242 and 246 may be about 0.4 eV to about 0.9 eV, for example, about 0.8 eV.

When the first to seventh quantum dots 251-257 are made of MnSi, a diameter of each of the first, third, fifth, and seventh quantum dots 251, 253, 255 and 257 may be about 3.68 nm, a diameter of the fourth quantum dot 254 may be about 5.82 nm, and a diameter of each of the second and sixth quantum dots 252 and 256 may be about 18 nm.

Since the absorption coefficient for the bandgap of about 2.3 eV may be about 2536517.1, the minimum thickness of each of the first, third, fifth, and seventh absorption sublayers 241, 243, 245 and 247 may be about 3.94 nm, and therefore, nearly a single layer of the first, third, fifth, or seventh quantum dots 251, 253, 255 or 257 may form the first, third, fifth, or seventh absorption sublayers 241, 243, 245 or 247 having the minimum thickness.

Since the absorption coefficient for the bandgap of about 1.4 eV may be about 1137167.9, the minimum thickness of the fourth absorption sublayer 244 may be about 5.82 nm, and thus nearly two layers of the fourth quantum dots 254 may form the fourth absorption sublayer 244 having the minimum thickness.

Since the absorption coefficient for about 0.8 eV may be about 564831.9, the minimum thickness of each of the second and sixth absorption sublayers 242 and 246 may be about 18.0 nm, and thus nearly a single layer of the second or sixth quantum dots 252 or 256 may form the second or sixth absorption sublayers 242 or 246 having the minimum thickness.

The first and second electrodes 220 and 260 may have substantially the same structure as first and second electrodes 120 and 160 shown in FIG. 1.

A solar cell according to an example embodiment is described in detail with reference to FIG. 3.

FIG. 3 is a schematic sectional view of a solar cell according to an example embodiment.

Referring to FIG. 3, a solar cell 300 according to an example embodiment includes a first electrode (or a lower electrode) 320, a light absorption layer 340, and a second electrode (or an upper electrode) 3260, which are deposited in sequence.

The light absorption layer 340 is disposed between the first electrode 320 and the second electrode 360, and may absorb photons to produce electrons and holes. The light absorption layer 140 may include a first absorption sublayer 341, a second absorption sublayer 342, a third absorption sublayer 343, a fourth absorption sublayer 344, and a fifth absorption sublayer 345.

Among the first to fifth absorption sublayers 341-345, the outermost sublayers, i.e., the first absorption sublayer 341 and the fifth absorption sublayer 345 may contact the first electrode 320 and the second electrode 360, respectively. The third absorption sublayer 343 is the innermost sublayer. The second absorption sublayer 342 is disposed between the first absorption sublayer 341 and the third absorption sublayer 343, and the fourth absorption sublayer 344 is disposed between the fifth absorption sublayer 345 and the fifth absorption sublayer 345.

The first to fifth absorption sublayers 341-345 may include first to fifth quantum dots (or nanoparticles) 351-355, respectively. The first quantum dots 351 may contact the first electrode 320, and the fifth quantum dots 355 may contact the second electrode 360. The quantum dots 351-355 in each of the absorption sublayers 341-345 may have substantially the same size. At least one of the first to fifth absorption sublayers 341-345 may further include ligands (not shown) that may keep distances between the quantum dots 351-355 and may fix the quantum dots 351-355. For example, the first absorption sublayer 341 may further include ligands, and the ligands instead of the first quantum dots 351 may contact the first electrode 320. Similarly, the fifth absorption sublayer 345 may further include ligands, and the ligands instead of the fifth quantum dots 355 may contact the second electrode 360.

The outermost quantum dots, i.e., the first and fifth quantum dots 351 and 355 may be the smallest, and the inner quantum dots, i.e., the second to fourth quantum dots 352-354 may be equal to or larger than the first and fifth quantum dots 351 and 355 in size. Among the second to fourth quantum dots 352-354, the second quantum dot 352 adjacent to the first quantum dot 351 and the fourth quantum dot 354 adjacent to the fifth quantum dot 355 may be larger than and the innermost quantum dot, i.e., the third quantum dot 353 in size.

According to an example embodiment, the sizes of the first quantum dot 351 to the fifth quantum dots 355 may be small-large-medium-large-small in sequence.

According to an example embodiment, the first quantum dot 351 may have substantially the same size as the fifth quantum dot 355.

According to an example embodiment, the second quantum dot 352 may have substantially the same size as the fourth quantum dot 354.

According to an example embodiment, an arrangement of the first to fifth quantum dots 351-355 may be symmetrical in the vertical direction.

According to an example embodiment, the structures of the first to fifth absorption sublayers 341-345 may be symmetrical with respect to the third absorption sublayer 343.

According to an example embodiment, the first to fifth absorption sublayers 341-345 may have substantially the same thickness.

According to an example embodiment, the bandgap of each of the first and fifth absorption sublayers 341 and 345 may be about 1.8 eV to about 5 eV, for example, about 2.3 eV. The bandgap of the third absorption sublayer 343 may be about 0.8 eV to about 1.8 eV, for example, about 1.4 eV. The bandgap of each of the second and fourth absorption sublayers 342 and 343 may be about 0.4 eV to about 0.9 eV, for example, about 0.8 eV. The sizes of the quantum dots 351-355 may be substantially the same as described above.

The first and second electrodes 320 and 360 may have substantially the same structure as first and second electrodes 120 and 160 shown in FIG. 1.

The open-circuit voltage of the solar cells 200 and 300 shown in FIG. 2 and FIG. 3 may be substantially the same as a voltage of the outer sublayer 241, 247, 341 or 345, and a short-circuit current (Jsc) may be a sum of the currents of all the absorption sublayers 241-247 and 341-345.

While some example embodiments have been particularly shown and described, it will be understood by one of ordinary skill in the art that variations in form and detail may be made therein without departing from the spirit and scope of the claims.

What is claimed is:

1. A solar cell comprising:
a first electrode;
a second electrode spaced apart from the first electrode; and
a light absorption layer between the first electrode and the second electrode, the light absorption layer including a first absorption sublayer, a second absorption sublayer, and a third absorption sublayer,
wherein the first absorption sublayer contacts the first electrode and includes a first quantum dot,
the second absorption sublayer is between the first absorption sublayer and the third absorption sublayer and includes a second quantum dot,
the third absorption sublayer contacts the second electrode and includes a third quantum dot, and
the second quantum dot is larger than the first quantum dot and the third quantum dot.

2. The solar cell of claim 1, wherein the first quantum dot and the third quantum dot are the same size.

3. The solar cell of claim 1, wherein
the first absorption sublayer includes at least one layer of the first quantum dot,
the second absorption sublayer includes at least two layers of the second quantum dot, and
the third absorption sublayer includes at least one layer of the third quantum dot.

4. The solar cell of claim 1, wherein
the first absorption sublayer has a bandgap from about 1.8 eV to about 5 eV,
the second absorption sublayer has a bandgap from about 0.8 eV to about 1.8 eV, and
the third absorption sublayer has a bandgap from about 1.8 eV to about 5 eV.

5. The solar cell of claim 4, wherein
the first absorption sublayer is configured to absorb light having a wavelength from about 350 nm to about 650 nm,
the second absorption sublayer is configured to absorb light having a wavelength from about 650 nm to about 1,200 nm, and
the third absorption sublayer is configured to absorb light having a wavelength from about 350 nm to about 650 nm.

6. The solar cell of claim 1, wherein
the first absorption sublayer has a bandgap from about 0.8 eV to about 1.8 eV,
the second absorption sublayer has a bandgap from about 0.4 eV to about 0.9 eV, and
the third absorption sublayer has a bandgap from about 0.8 eV to about 1.8 eV.

7. The solar cell of claim 6, wherein
the first absorption sublayer is configured to absorb light having a wavelength from about 650 nm to about 1,200 nm,
the second absorption sublayer is configured to absorb light having a wavelength from about 1,100 nm to about 2,500 nm, and
the third absorption sublayer is configured to absorb light having a wavelength from about 650 nm to about 1,200 nm.

8. The solar cell of claim 1, wherein
the first absorption sublayer has a bandgap from about 1.8 eV to about 5 eV,
the second absorption sublayer has a bandgap from about 0.4 eV to about 0.9 eV, and
the third absorption sublayer has a bandgap from about 1.8 eV to about 5 eV.

9. The solar cell of claim 8, wherein
the first absorption sublayer is configured to absorb light having a wavelength from about 350 nm to about 650 nm,
the second absorption sublayer is configured to absorb light having a wavelength from about 1,100 nm to about 2,500 nm, and
the third absorption sublayer is configured to absorb light having a wavelength from about 350 nm to about 650 nm.

10. The solar cell of claim 1, further comprising:
a fourth absorption sublayer between the first absorption sublayer and the second absorption sublayer, the fourth absorption sublayer including a fourth quantum dot larger than the first, second and third quantum dots; and
a fifth absorption sublayer between the second absorption sublayer and the third absorption sublayer, the fifth absorption sublayer including a fifth quantum dot larger than the first, second and third quantum dots.

11. The solar cell of claim 10, wherein the fourth quantum dot and the fifth quantum dot are the same size.

12. The solar cell of claim 10, further comprising:
a sixth absorption sublayer between the second absorption sublayer and the fourth absorption sublayer, the sixth absorption sublayer including a sixth quantum dot smaller than the second, fourth, and fifth quantum dots; and
a seventh absorption sublayer between the second absorption sublayer and the fifth absorption sublayer, the seventh absorption sublayer including a seventh quantum dot smaller than the second, fourth, and fifth quantum dots.

13. The solar cell of claim 12, wherein
the fourth quantum dot and the fifth quantum dot are the same size,
the sixth quantum dot, the first quantum dot and the third quantum dot are the same size, and
the seventh quantum dot, the first quantum dot and the third quantum dot are the same size.

14. The solar cell of claim 10, wherein
each of the first absorption sublayer and the third absorption sublayer has a bandgap from about 1.8 eV to about 5 eV,
the second absorption sublayer has a bandgap from about 0.8 eV to about 1.8 eV, and
each of the fourth absorption sublayer and the fifth absorption sublayer has a bandgap from about 0.4 eV to about 0.9 eV.

15. The solar cell of claim 14, wherein
each of the first absorption sublayer and the third absorption sublayer is configured to absorb light having a wavelength from about 350 nm to 650 nm,
the second absorption sublayer is configured to absorb light having a wavelength from about 650 nm to about 1,200 nm, and
each of the fourth absorption sublayer and the fifth absorption sublayer is configured to absorb light having a wavelength from about 1,100 nm to about 2,500 nm.

16. The solar cell of claim 10, wherein the first, second, third, fourth and fifth absorption sublayers have a same thickness.

17. The solar cell of claim 10, wherein the first, second, third, fourth and fifth absorption sublayers have a symmetrical structure with respect to the third absorption sublayer.
